(19) United States
(12) Patent Application Publication
(10) Pub. No.: US 2015/0316098 A1
(43) Pub. Date: Nov. 5, 2015

(54) BEARING MECHANISM AND TRANSFER DEVICE

(71) Applicant: TOKYO ELECTRON LIMITED, Tokyo (JP)

(72) Inventor: Tsutomu HIROKI, Nirasaki City (JP)

(21) Appl. No.: 14/689,086

(22) Filed: Apr. 17, 2015

(30) Foreign Application Priority Data
Apr. 30, 2014 (JP) 2014-093480

(51) Int. Cl. F16C 33/66; B25J 11/00; H01L 21/677; F16C 19/06

(52) U.S. Cl. CPC F16C 33/6644; F16C 19/06; B25J 11/0095; H01L 21/67706

(57) ABSTRACT

A bearing mechanism includes: a bearing that includes an inner and outer races, the outer race facing the inner race and a rolling element being interposed between the inner and outer races; a magnet that includes a first and second magnetic poles and extends between the first and second magnetic poles along an axial direction of the bearing, the first magnetic pole being in contact with an end surface of the outer race and the second magnetic pole opposing the first magnetic pole; a yoke that forms a magnetic circuit together with the bearing and the magnet, the yoke extending between the second magnetic pole and an end surface of the inner race so that the yoke is in contact with the second magnetic pole and faces the end surface of the inner race with a gap interposed therebetween; and a magnetic fluid held by the magnetic circuit.

### CROSS-REFERENCE TO RELATED APPLICATION

This application claims the benefit of priority to Japanese Patent Application No. 2014-093480, filed on Apr. 30, 2014, in the Japan Patent Office, the disclosure of which is incorporated herein in its entirety by reference.

### TECHNICAL FIELD

The present disclosure relates to a bearing mechanism and transfer device.

### BACKGROUND

In a manufacturing process of electronic devices such as semiconductor devices, a target object is transferred to various processing chambers by transfer devices such as a robot arm and so forth arranged in a vacuum container. In a joint portion of the transfer device, a driving axis that transfers a driving force and a bearing that rotatably-supports the driving axis are installed. In general, lubrication grease is applied to a bearing. However, grease can be scattered in a vacuum container and cause organic contamination that lowers the degree of cleanliness in the vacuum container.

On the other hand, in the driving axis that transfers a driving force into the vacuum container, it has been known that magnetic fluid is used as a lubricant instead of the grease. For example, a bearing device has been known wherein a bearing and two magnets are installed between a driving axis and a housing. One of the two magnets is fixed to the housing to make contact with an outer race of the bearing. The other of the two magnets is fixed to the driving axis to make contact with an inner race of the bearing. In this bearing device, a magnetic fluid provided to a lubrication target in the bearing is held by a magnetic circuit formed by the bearing and the two magnets.

Also, a rotary introduction machine has been known wherein a pair of ball bearings, a first spacer and a second spacer are installed between a driving axis and a casing. The first spacer is arranged between outer races of the pair of ball bearings. Both ends of the first spacer are magnetized to N pole and S pole, respectively. The second spacer is made of non-magnetic material and is arranged between inner races of the pair of ball bearings. In this rotary introduction machine, a magnetic circuit is formed to start from the first spacer, pass through one of the ball bearings, an axis part of the driving axis and the other of the ball bearings, and then return to the first spacer. A magnetic fluid provided to a lubrication target in the ball bearings is held by the magnetic circuit.

In the aforementioned bearing device, since the magnet in contact with the inner race of the bearing is fixed to the driving axis, it is likely that the rotating speed of the driving axis decreases due to the increase in weight thereof. Similarly, in the aforementioned rotary introduction machine, since the second spacer is fixed between the inner races of the pair of ball bearings, it is likely that the rotating speed of the driving axis (rotation axis) decreases.

### SUMMARY

Some embodiments of the present disclosure provide a bearing mechanism and a transfer device, which are capable of preventing organic contamination in a vacuum container without hindering rotation of a rotation axis.

According to one aspect of the present disclosure, there is provided a bearing mechanism configured to be accommodated in a vacuum container. The bearing mechanism includes: a bearing that includes an inner race and an outer race, the outer race facing the inner race and a rolling element being interposed between the inner race and the outer race; a magnet that includes a first magnetic pole and a second magnetic pole and extends between the first and second magnetic poles along an axial direction of the bearing, the first magnetic pole being in contact with an end surface of the outer race and the second magnetic pole opposing the first magnetic pole; a yoke that forms a magnetic circuit together with the bearing and the magnet, the yoke extending between the second magnetic pole and an end surface of the inner race so that the yoke is in contact with the second magnetic pole and faces the end surface of the inner race with a gap interposed therebetween; and a magnetic fluid held by the magnetic circuit.

According to other aspect of the present disclosure, there is provided a transfer device configured to be accommodated in a vacuum container. The transfer device includes: a rotation axis; a first member coupled with the rotation axis; a second member having a through-hole formed therein, the rotation axis being inserted through the through-hole; and a pair of bearing mechanisms installed between an outer peripheral surface of the rotation axis and a wall surface of the second member defining the through-hole, the bearing mechanisms being arranged along an axial direction of the rotation axis. Each of the bearing mechanisms includes: a bearing that includes an inner race being in contact with the outer peripheral surface of the rotation axis, an outer race being contact with the wall surface of the second member, and a rolling element interposed between the inner and outer races; a magnet that includes a first magnetic pole and a second magnetic pole and extends between the first and second magnetic poles along the axial direction, the first magnetic pole being in contact with an end surface of the outer race and the second magnetic pole opposing the first magnetic pole; a yoke that forms a magnetic circuit together with the bearing and the magnet, the yoke extending between the second magnetic pole and an end surface of the inner race so that the yoke is in contact with the second magnetic pole and faces the end surface of the inner race with a gap interposed therebetween, and the yoke not being in contact with the inner race and the rotation axis; and a magnetic fluid held by the magnetic circuit.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 illustrates an example of a substrate processing system including a vacuum container which accommodates a transfer device and a bearing mechanism according to an embodiment of the present disclosure.

FIG. 2 is a perspective view illustrating a transfer arm according to the embodiment.

FIG. 3 is a perspective view illustrating a first arm.

FIG. 4 is a sectional view of a joint part.

FIG. 5 is an enlarged sectional view of the joint part illustrated in FIG. 4.

FIG. 6 is a sectional view illustrating a modified example of the bearing mechanism.

### DETAILED DESCRIPTION

Reference will now be made in detail to various embodiments, examples of which are illustrated in the accompanying drawings. In the following detailed description, numerous specific details are set forth in order to provide a thorough understanding of the inventive aspects of this disclosure. However, it will be apparent to one of ordinary skill in the art that the inventive aspects of this disclosure may be practiced without these specific details. In other instances, well-known methods, procedures, systems, and components have not been described in detail so as not to unnecessarily obscure aspects of the various embodiments.

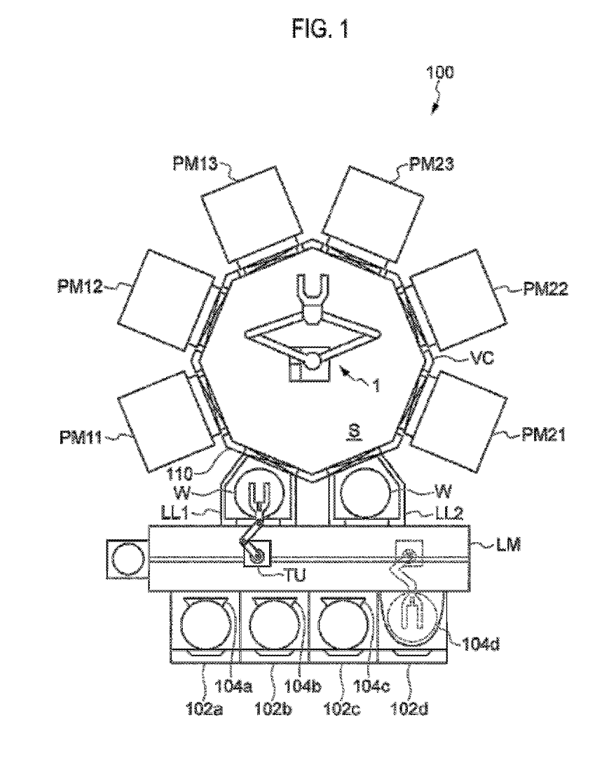

First, an example of a substrate processing system including a vacuum container which accommodates a transfer device and a bearing mechanism according to an embodiment will be explained with reference to FIG. 1. A substrate processing system 100 illustrated in FIG. 1 is a system that performs a plurality of processes on an object to be processed. The substrate processing system 100 includes mounting stages 102a to 102d, a loader module LM, load-lock chambers LL1 and LL2, process modules PM11 to PM23, and a transfer chamber 110.

The loader module LM has a box-like shape having a long length in one direction (longitudinal direction). The mounting stages 102a to 102d are arranged along one of a pair of edges of the loader module LM extending in the longitudinal direction. Accommodating containers 104a to 104d are placed on the mounting stages 102a to 102d, respectively. Objects to be processed are accommodated in the accommodating containers 104a to 104d.

The loader module LM has a chamber wall that defines an atmospheric transfer space within the loader module LM. The loader module LM has a transfer unit TU installed in the transfer space. The transfer unit TU of the loader module LM takes out an object to be processed (for example, a wafer W) from one of the accommodating containers 104a to 104d and transfers the taken-out object to be processed to one of the load-lock chambers LL1 and LL2.

The load-lock chambers LL1 and LL2 serve as preliminary depressurization chambers. In the substrate processing system 100, an object to be processed is accommodated in one of the preliminary depressurization chambers, i.e., one of the load-lock chambers LL1 and LL2, before the object to be processed is transferred to the transfer chamber 110. The load-lock chambers LL1 and LL2 are installed between the loader module LM and the transfer chamber 110, and are arranged along the other edge of the loader module LM on which the mounting stages 102a to 102d are not mounted and which extends in the longitudinal direction. Opening/closing gate valves are respectively installed between the load-lock chamber LL1 and the loader module LM, between the load-lock chamber LL1 and the transfer chamber 110, between the load-lock chamber LL2 and the loader module LM, and between the load-lock chamber LL2 and the transfer chamber 110.

The process modules PM11 to PM23 that perform various processes such as a plasma treatment, heat treatment and so forth on the object to be processed are connected to the transfer chamber 110 through the gate valves. The transfer chamber 110 includes a vacuum container VC of the present embodiment. The inner space of the vacuum container VC is a transfer space S which can be depressurized to a desired pressure. In the transfer space S, a transfer arm 1 as the transfer device of the present embodiment is accommodated. The transfer arm 1 takes out an object to be processed from one of the load-lock chambers LL1 and LL2 and transfers the object to be processed to one of the process modules PM11 to PM23. The transfer arm 1 may transfer the object to be processed between two of the transfer modules PM11 to PM23. Also, the transfer arm 1 may take out an object processed by the process modules PM11 to PM23 from the process modules PM11 to PM23 and transfer the processed object to one of the load-lock chambers LL1 and LL2.

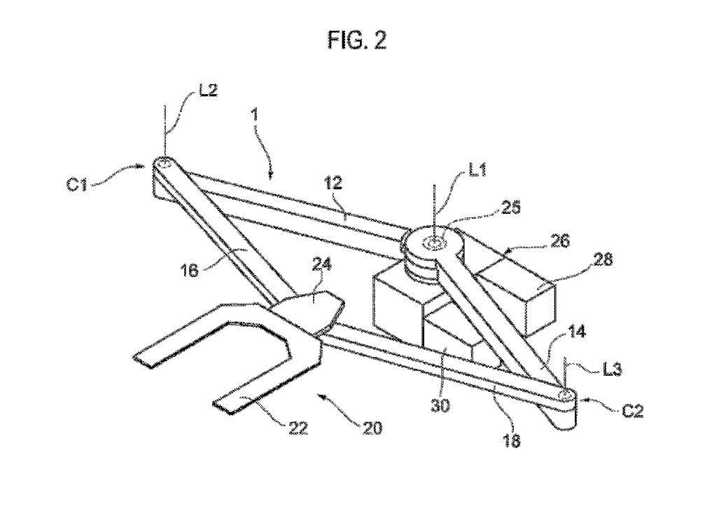

Hereinafter, the transfer device of the present embodiment accommodated in a vacuum container such as the vacuum container VC of the substrate processing system 100 will be explained. FIG. 2 is a perspective view illustrating the transfer arm 1 as the transfer device according to the present embodiment. The transfer arm 1 illustrated in FIG. 2 is arranged in a vacuum container such as the vacuum container VC and transfers an object to be processed to process chambers such as the process modules PM11 to PM23. As illustrated in FIG. 2, the transfer arm 1 includes a first arm 12, a second arm 14, a first link 16, a second link 18 and a pick 20. The first arm 12 and the second arm 14 correspond to a second member of the present embodiment, and the first link 16 and the second link 18 correspond to a first member of the present embodiment.

The first arm 12 has first and second ends. The second arm 14 also has first and second ends. Each of the first arm 12 and the second arm 14 extends from the first end to the second end along a direction perpendicular to a first axis line L1. The first end of the first arm 12 and the first end of the second arm 14 are axially supported by a central hub 25 of a driving device 26. The first arm 12 rotates about the first axis line L1 of the central hub 25 by a driving power from a first motor 28 provided in the driving device 26. The second arm 14 rotates about the first axis line L1 of the central hub 25 by a driving power from a second motor 30 provided in the driving device 26.

The first link 16 has first and second ends, and extends from the first end to the second end along a direction perpendicular to a second axis line L2 passing through the second end of the first arm 12. The first end of the first link 16 is connected to the second end of the first arm 12. The second end of the first link 16 is connected to the pick 20. The first link 16 is rotatable about the center of the second axis line L2. The second link 18 also has first and second ends, and extends from the first end to the second end along a direction perpendicular to a third axis line L3 passing through the second end of the second arm 14. The first end of the second link 18 is connected to the second end of the second arm 14. The second end of the second link 18 is connected to the pick 20. The second link 18 is rotatable about the center of the third axis line L3. The second axis line L2 and the third axis line L3 are in parallel with the first axis line L1.

In the transfer arm 1, if the first arm 12 and the second arm 14 rotates in directions approaching each other, i.e., directions that make the angle between the first arm 12 and the second arm 14 decrease, the first link 16 and the second link 18 rotates in directions approaching each other, i.e., directions that make the angle between the first link 16 and the second link 18 decrease. By these movements, the transfer arm 1 is extended and the pick 20 moves in a direction away from the first axis line L1. On the other hand, if the first arm 12 and the second arm 14 rotate in directions away from each other, i.e., directions that make the angle between the first arm 12 and the second arm 14 increase, the first link 16 and the second link 18 rotates in directions away from each other, i.e., directions that make the angle between the first link 16 and the second link 18 increase. By these movements, the transfer arm 1 is contracted and the pick 20 moves in a direction approaching the first axis line L1.

The pick 20 includes a pick main body 22 and a base plate 24. The pick main body 22 is a member on which an object to be processed is mounted. The pick main body 22 is, for example, a U-shaped plate member when viewed from top. The pick main body 22 is coupled with the base plate 24 by coupling means of a screw bolt and so forth. The base plate 24 is supported by the second ends of the first and second links 16 and 18. The frog-leg type transfer arm 1 is constituted by the pick 20, the first link 16, the second link 18, the first arm 12 and the second arm 14.

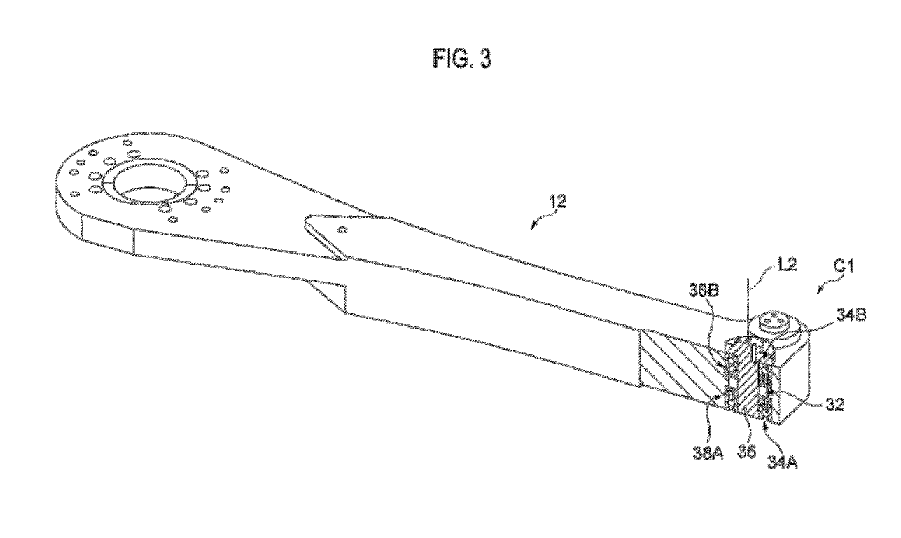

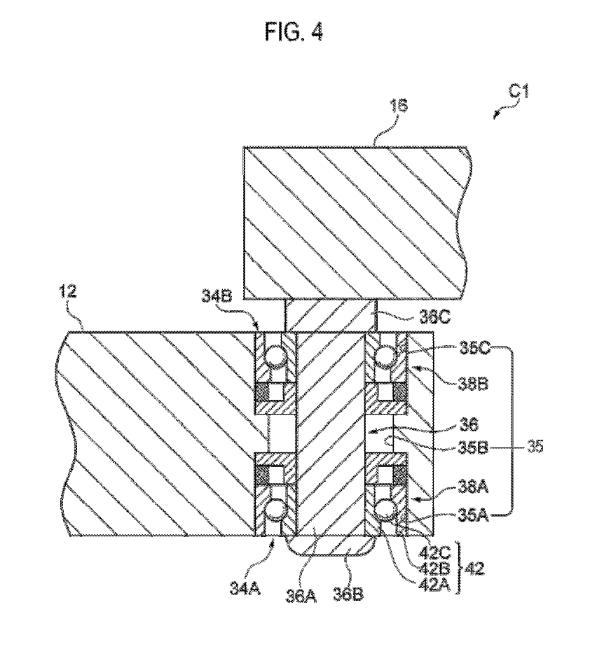

Next, a joint of the first arm 12 and the first link 16, i.e., a joint part C1, will be explained with reference to FIGS. 3 and 4. Since a joint of the second arm 14 and the second link 18, i.e., a joint part C2, has the same configuration with the joint part C1, the joint part C1 only will be explained below. FIG. 3 is a perspective view illustrating the first arm 12. FIG. 4 is a sectional view of the joint part C1. Although FIG. 3 is a diagram regarding a dual frog-leg arm having two picks and thus illustrates two joint parts, an explanation thereof will be omitted.

In the first arm 12, a through-hole 32 is formed to penetrate the second end of the first arm 12 along an extending direction of the second axis line L2. The central axis line of the through-hole 32 substantially coincides with the second axis line L2. The through-hole 32 includes a first opening 34A and a second opening 34B, and is extended between the first opening 34A and the second opening 34B. A rotation axis 36 is inserted through the through-hole 32. The central axis of the rotation axis 36 substantially coincides with the second axis line L2.

The rotation axis 36 includes a main body portion 36A, a base end portion 36B and a leading end portion 36C. The diameters of the base end portion 36B and the leading end portion 36C are slightly larger than that of the main body portion 36A. The main body portion 36A is arranged within the through-hole 32. The base end portion 36B and the leading end portion 36C are arranged outside the through-hole 32. The first end of the first link 16 is engaged with the leading end portion 36C (see FIG. 4).

A pair of bearing mechanisms, i.e., a first bearing mechanism 38A and a second bearing mechanism 38B, is located between an outer peripheral surface of the rotation axis 36 and a wall surface 35 forming the through-hole 32. The first bearing mechanism 38A and the second bearing mechanism 38B are arranged along the axial direction of the rotation axis 36, i.e., the direction of the second axis line L2.

The wall surface 35 of the first arm 12 defining the through-hole 32 includes a first portion 35A, a second portion 35B and a third portion 35C. The first portion 35A is positioned at the side of the first opening 34A and the third portion 35C is positioned at the side of the second opening 34B. The second portion 35B is formed between the first portion 35A and the third portion 35C along the extended direction of the second axis line L2. The second portion 35B protrudes towards the second axis line L2 more than the first and third portions 35A and 35C. That is to say, the diameter of the through-hole 32 is reduced in the middle. The first bearing mechanism 38A is arranged between the rotation axis 36 and the first portion 35A of the wall surface 35. The second bearing mechanism 38B is arranged between the rotation axis 36 and the third portion 35C of the wall surface 35. In other words, the first bearing mechanism 38A is arranged closer to the first opening 34A than the second bearing mechanism 38B, and the second bearing mechanism 38B is arranged closer to the second opening 34B than the first bearing mechanism 38A.

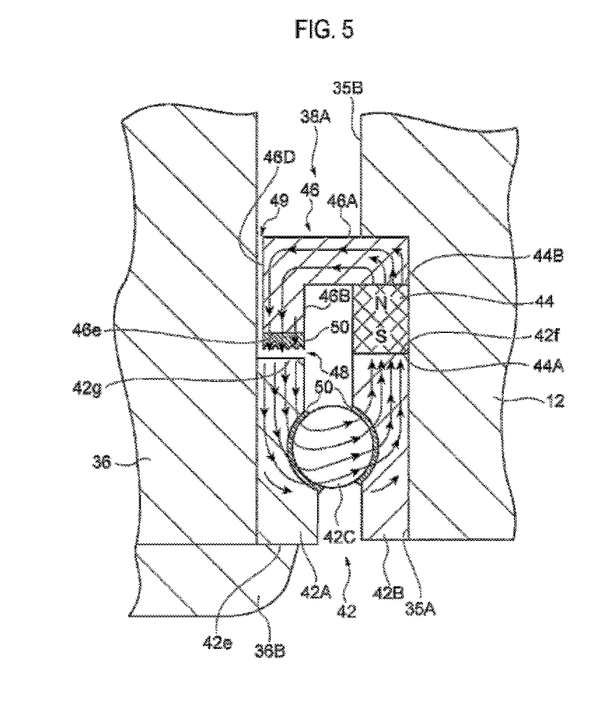

Next, the first bearing mechanism 38A will be explained in detail with reference to FIG. 5. Since configurations of the first bearing mechanism 38A and the second bearing mechanism 38B are symmetric in the extending direction of the second axis line L2, the first bearing mechanism 38A only will be explained below. FIG. 5 is an enlarged sectional view of the bearing mechanism. As illustrated in FIG. 5, the first bearing mechanism 38A includes a bearing 42, a magnet 44 and a yoke 46.

The bearing 42 includes an inner race 42A, an outer race 42B and a rolling element 42C. The inner race 42A extends in a ring shape centered about the second axis line L2 and makes contact with the rotation axis 36. An end surface 42e of the inner race 42A makes contact with the base end portion 36B of the rotation axis 36. The outer race 42B is disposed further radially outward than the inner race 42A with respect to the second axis line L2, and extends in a ring shape centered about the second axis line L2. In other words, the outer race 42B is coaxially installed with the inner race 42A and is arranged to face the inner race 42A. The outer race 42B is fixed to the first portion 35A of the wall surface 35. The rolling element 42C is interposed between the inner race 42A and the outer race 42B. The bearing 42 rotatably supports the rotation axis 36. An angular bearing as illustrated in FIG. 5, for example, may be used as the bearing 42.

The magnet 44 has a cylinder shape having a diameter larger than that of the rotation axis 36. The magnet 44 and the rotation axis 36 are coaxially installed. The magnet 44 has a first magnetic pole 44A in one end thereof and has a second magnetic pole 44B in the other end thereof, i.e., in a side opposing the first magnetic pole 44A. For example, the first magnetic pole 44A and the second magnetic pole 44B are S-pole and N-pole, respectively. A permanent magnet, e.g., a neodymium magnet, may be used as the magnet 44. The magnet 44 makes contact with an end surface 42f of the outer race 42B at the first magnetic pole 44A. The magnet 44 extends, in a direction along the second axis line L2, between the first magnetic pole 44A and the second magnetic pole 44B.

The yoke 46 has a substantially cylinder shape having a diameter larger than that of the rotation axis 36. The yoke 46 and the rotation axis 36 are coaxially installed. The yoke 46 extends between the second magnetic pole 44B and an end surface 42g of the inner race 42A, so that the yoke 46 makes contact with the second magnetic pole 44B and faces the end surface 42g of the inner race 42A with a gap 48 interposed therebetween. The yoke 46 is arranged so that it does not contact the inner race 42A and the rotation axis 36. Specifically, the yoke 46 includes a first portion 46A and a second portion 46B. The first portion 46A has an annular plate shape and extends radially with respect to the second axis line L2. The second portion 46B has a cylindrical shape and continues from the first portion 46A. The second portion 46B extends, in the vicinity of the outer peripheral surface of the rotation axis 36, in the extending direction of the second axis line L2. In other words, the yoke 46 has a substantially L-shaped cross section. The yoke 46 is made of a ferromagnetic material. The yoke 46 may be made of a martensitic stainless steel, e.g., SUS440C.

The first portion 46A of the yoke 46 is in contact with the second magnetic pole 44B. In the present embodiment, the first portion 46A of the yoke 46 is insertedly supported by a stepped surface between the first portion 35A and the second portion 35B and the second magnetic pole 44B. An end surface 46e of the second portion 46B of the yoke 46 faces the end surface 42g of the inner race 42A with the gap 48 therebetween. Further, an inner peripheral surface 46D of the second portion 46B of the yoke 46 is spaced apart from the outer peripheral surface of the rotation axis 36, whereby there is a gap 49 between the inner peripheral surface 46D and the outer peripheral surface of the rotation axis 36.

In the first bearing mechanism 38A of the present embodiment, as illustrated in FIG. 5, the magnet 44 and the yoke 46 are arranged in a more inner side of the through-hole 32 in the extending direction of the second axis line L2 than the bearing 42. In other words, the magnet 44 and the yoke 46 are arranged closer to the second opening 34B than the bearing 42.

In the first bearing mechanism 38A, a magnetic circuit is formed to start from the second magnetic pole 44B of the magnet 44, pass through the yoke 46, the inner race 42A, the rolling element 42C and the outer race 42B, and return to the first magnetic pole 44A of the magnet 44. The arrows illustrated in FIG. 5 indicate a direction of magnetic flux in the magnetic circuit. Although the gap 48 is formed between the yoke 46 and the inner race 42A, since magnetism is propagated even in a vacuum, the magnetically-continuous magnetic circuit is formed in the first bearing mechanism 38A.

A magnetic fluid 50 is filled in the first bearing mechanism 38A. The magnetic fluid 50 is a liquid in which magnetic fine particles are dispersed in a base oil using a surfactant. The magnetic fluid 50 has characteristics in that, when being placed in a magnetic field, it flows along a direction of the magnetic field. For example, a fluoric base oil having magnetite fine particles dispersed therein may be used as the magnetic fluid 50. The magnetic fluid 50 is held along the magnetic circuit formed in the first bearing mechanism 38A. Specifically, as illustrated in FIG. 5, the magnetic fluid 50 is held between the inner race 42A and the rolling element 42C and between the outer race 42B and the rolling element 42C in the bearing 42. The magnetic fluid 50 held in the bearing 42 serves as a lubricant of the bearing 42. Some of the magnetic fluid 50 is held in the gap 48 by the magnetic field in the magnetic circuit.

By the joint part C1 configured as described above, the second end of the first arm 12 and the first end of the first link 16 are connected to each other, whereby the first link 16 connected to the leading end portion 36C of the rotation axis 36 rotates about the second axis line L2 by the driving force transferred via the first arm 12.

In the aforementioned first bearing mechanism 38A, the magnetic fluid 50 provided to a lubrication target area in the bearing 42 is held by a magnetic force of the magnetic circuit formed by the bearing 42, the magnet 44 and the yoke 46. Accordingly, the magnetic fluid 50 is suppressed from being scattered within the vacuum container and organic contamination in the vacuum container can be suppressed. In addition, in the first bearing mechanism 38A, no component of the magnetic circuit other than the inner race 42A is in contact with the rotation axis 36, and thus rotation of the rotation axis 36 is prevented from being hindered. Therefore, by using the transfer arm 1 having a joint portion including the first and second bearing mechanisms 38A and 38B, degradation in movability of the transfer arm 1 due to hindrance of the rotation of the rotation axis 36 can be prevented.

In the aforementioned embodiment, since each of the first and second bearing mechanisms 38A and 38B is provided with the magnet 44, a magnetic circuit with a strong magnetic field can be formed in each of the first and second bearing mechanisms 38A and 38B. Therefore, the magnetic fluid 50 can be strongly held in the each of the first and second bearing mechanisms 38A and 38B. Further, in the aforementioned embodiment, the yoke 46 is in contact with neither the inner race 42A nor the rotation axis 36, whereby the magnet 44 is brought into contact with the rotation axis 36 via the inner race 42A, the rolling element 42C and the outer race 42B. In some cases of performing a process accompanying heating in the process modules, the transfer arm 1 may receive heat from a heated object to be processed. However, the rolling element 42C is in line-contact with both of the inner race 42A and the outer race 42B and heat conductivity between the inner race 42A and the outer race 42B is very low, whereby the first bearing mechanism 38A has a structure that makes it difficult for heat of the rotation axis 36 to be transferred to the magnet 44. Therefore, according to the aforementioned embodiment, a permanent magnet with low heat resistance, e.g., a neodymium magnet or the like, can be employed as the magnet 44. Moreover, even if particles are generated in the bearing 42, the magnetic fluid 50 held in the gap 48 can capture the particles.

In the case of using an angular bearing as the bearing 42, a path in the magnetic circuit via the inner race 42A, the rolling element 42C and the outer race 42B is configured to be oblique with respect to a radial direction of the rotation axis 36. In this case, the length of the magnetic circuit formed in each of the first and second bearing mechanisms 38A and 38B decreases. Further, contact areas between the inner race 42A and the rolling element 42C and between the outer race 42B and the rolling element 42C become relatively large. Therefore, magnetic reluctance can be reduced. In addition, as illustrated in FIG. 4, the bearing 42 of the first bearing mechanism 38A and the bearing 42 of the second bearing mechanism 38B may be arranged to face each other, i.e., in back-to-back pairs, whereby moment load capacity can be enhanced.

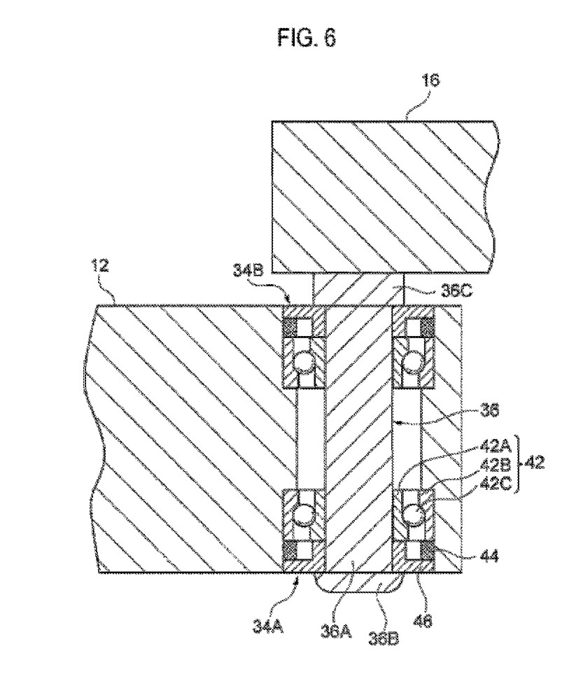

In the aforementioned embodiment, the yoke 46 is arranged in a more inner side of the through-hole 32 than the bearing 42. With this configuration, a gap between the pair of bearing mechanisms, i.e., the first bearing mechanism 38A and the second bearing mechanism 38B, can be secured without increasing a thickness of the first arm 12 in comparison with the embodiment of FIG. 6 to be described later. In addition, the rotation axis 36 is made of non-magnetic material in the aforementioned embodiment. For example, the rotation axis 36 is made of an austenite stainless steel, e.g., SUS304. Since such a rotation axis 36 has high corrosion resistance, a lifetime of the transfer arm 1 can be extended.

The present disclosure is not limited to the aforementioned embodiment but a variety of modifications may be made. For example, as illustrated in FIG. 6, the magnet 44 and the yoke 46 in the first bearing mechanism 38A may be arranged closer to the first opening 34A than the bearing 42, and the magnet 44 and the yoke 46 in the second bearing mechanism 38B may be arranged closer to the second opening 34B than the bearing 42. In this case, since the yokes 46 serve as cover portions that cover the first opening 34A and the second opening 34B, particles generated in the bearing 42 are prevented from being scattered within the vacuum container. Therefore, a decrease in cleanliness in the vacuum container can be suppressed.

In the aforementioned embodiment, the first and second bearing mechanisms 38A and 38B are installed in the joint parts C1 and C2 of the transfer arm 1. However, a bearing mechanism within the spirit of the first and second bearing mechanisms 38A and 38B may be installed in other joint parts, e.g., the central hub 25, and further, may be installed in any types of transfer devices other than the transfer arm 1 as long as the transfer devices are arranged in a vacuum container. For example, the bearing mechanism of the aforementioned embodiment may be used for supporting a rotation axis of a roller that assists a carrier, which transfers an object to be processed within a vacuum container, to move in one direction. Since a transfer arm arranged in a vacuum container may receive heat from a transfer target object or the like, it is likely that the transfer arm is heated and a lubricating grease is volatilized. Further, since the transfer arm moves rapidly in the vacuum container, it is likely that the lubricating grease is scattered due to the inertia or the like acting thereon. Furthermore, since a part of the transfer arm accesses the process modules where higher-cleanliness is required than the inside of the vacuum container, it is not preferable to use the lubricating grease. In the bearing mechanism of the aforementioned embodiment, the magnetic fluid is held in the magnetic circuit, which dispels the aforementioned concerns. Moreover, since the bearing mechanism configured as the aforementioned embodiment is relatively small in size, it can be properly used for, in particular, a joint part of a transfer arm.

As described above, according to the various aspects and embodiments of the present disclosure, organic contamination in a vacuum container can be prevented without hindering rotation of a rotation axis.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A bearing mechanism configured to be accommodated in a vacuum container, the bearing mechanism comprising:
a bearing that includes an inner race and an outer race, the outer race facing the inner race and a rolling element being interposed between the inner race and the outer race;
a magnet that includes a first magnetic pole and a second magnetic pole and extends between the first and second magnetic poles along an axial direction of the bearing, the first magnetic pole being in contact with an end surface of the outer race and the second magnetic pole opposing the first magnetic pole;
a yoke that forms a magnetic circuit together with the bearing and the magnet, the yoke extending between the second magnetic pole and an end surface of the inner race so that the yoke is in contact with the second magnetic pole and faces the end surface of the inner race with a gap interposed therebetween; and
a magnetic fluid held by the magnetic circuit.

2. A transfer device configured to be accommodated in a vacuum container, the transfer device comprising:
a rotation axis;
a first member coupled with the rotation axis;
a second member having a through-hole formed therein, the rotation axis being inserted through the through-hole; and
a pair of bearing mechanisms located between an outer peripheral surface of the rotation axis and a wall surface of the second member defining the through-hole, the bearing mechanisms being arranged along an axial direction of the rotation axis,
wherein each of the bearing mechanisms includes:
a bearing that includes an inner race being in contact with the outer peripheral surface of the rotation axis, an outer race being in contact with the wall surface of the second member, and a rolling element interposed between the inner and outer races;
a magnet that includes a first magnetic pole and a second magnetic pole and extends between the first and second magnetic poles along the axial direction, the first magnetic pole being in contact with an end surface of the outer race and the second magnetic pole opposing the first magnetic pole;
a yoke that forms a magnetic circuit together with the bearing and the magnet, the yoke extending between the second magnetic pole and an end surface of the inner race so that the yoke is in contact with the second magnetic pole and faces the end surface of the inner race with a gap interposed therebetween, and the yoke not being in contact with the inner race and the rotation axis; and
a magnetic fluid held by the magnetic circuit.

3. The transfer device of claim 2, wherein the bearing is an angular bearing.

4. The transfer device of claim 2, wherein the rotation axis is made of non-magnetic material.

5. The transfer device of claim 2, wherein the through-hole extends between a first opening and a second opening opposing the first opening, and wherein the magnet and the yoke of one of the pair of the bearing mechanisms arranged in vicinity of the first opening are arranged closer to the second opening than the bearing of the one of the pair of the bearing mechanisms, and the magnet and the yoke of another one of the pair of the bearing mechanisms are arranged closer to the first opening than the bearing of the another one of the pair of the bearing mechanisms.

6. The transfer device of claim 2, wherein the through-hole extends between a first opening and a second opening opposing the first opening, and wherein the magnet and the yoke of one of the pair of the bearing mechanisms arranged in vicinity of the first opening are arranged closer to the first opening than the bearing of the one of the pair of the bearing mechanisms, and the magnet and the yoke of another one of the pair of the bearing mechanisms are arranged closer to the second opening than the bearing of the another one of the pair of the bearing mechanisms.
